(19) United States
(12) Patent Application Publication
(10) Pub. No.: US 2025/0278030 A1
(43) Pub. Date: Sep. 4, 2025

(54) OBJECT HOLDING DEVICE, EXPOSURE DEVICE, OBJECT MOVING METHOD, AND OBJECT HOLDING SYSTEM

(71) Applicant: NIKON CORPORATION, Tokyo (JP)

(72) Inventor: Koichi SAKATA, Tokyo (JP)

(73) Assignee: NIKON CORPORATION, Tokyo (JP)

(21) Appl. No.: 19/213,181

(22) Filed: May 20, 2025

Related U.S. Application Data
(63) Continuation of application No. PCT/JP2023/043473, filed on Dec. 5, 2023.

(30) Foreign Application Priority Data
Dec. 16, 2022 (JP) 2022-201284

(51) Int. Cl. G03F 7/00; G03F 7/20

(52) U.S. Cl. CPC G03F 7/70825; G03F 7/2002

(57) ABSTRACT

An object holding device includes a holding unit that holds an object and is driven in a first direction and a second direction orthogonal to the first direction in a horizontal plane, and a pair of linear motors that apply thrusts in the first and second directions to the holding unit, each of the linear motors including a first unit including armature modules each including a magnetic core having two or more protruding portions, which protrude in the second direction, and a coil wound around the magnetic core, currents of the same phase flowing through the coil, and a second unit including a magnet module that includes permanent magnets arranged in the first direction while changing poles and is arranged between two adjacent protruding portions, wherein a part of each of the permanent magnets is accommodated in a space sandwiched between the two adjacent protruding portions.

### CROSS-REFERENCE TO RELATED APPLICATION

This application is a continuation application of PCT/JP2023/043473, filed on Dec. 5, 2023, which claims the benefit of priority of the prior Japanese Patent Application No. 2022-201284, filed on Dec. 16, 2022, the entire contents of which are incorporated herein by reference.

### FIELD

A certain aspect of embodiments described herein relates to an object holding device, an exposure device, an object moving method, and an object holding system.

### BACKGROUND

In a lithography process for manufacturing electronic devices (microdevices) such as liquid crystal display devices and semiconductor devices (integrated circuits), a step-and-scan exposure device (so-called scanning stepper (also called a scanner)) is used which transfers the pattern formed on the mask onto a glass substrate or wafer (hereinafter collectively referred to as a “substrate”) by using an energy beam while synchronously moving the mask or reticle (hereinafter collectively referred to as a “mask”) and the substrate along a predetermined scanning direction (scan direction).

In exposure devices, the development of light sources represented by UV-LEDs (Ultraviolet-Light Emitting Diodes) has dramatically improved the illuminance of the illumination system, and the amount of exposure can be secured even when various stages, including mask stages, are driven at high speed. Therefore, there is an increasing demand for higher driving speeds of various stages including mask stages. The throughput is improved by increasing the driving speeds of various stages.

For example, a linear motor is used as a driving device to drive the mask stage in the scanning direction as disclosed in, for example, Japanese Patent Application Laid-Open No. 2017-15995 (Patent Document 1).

### SUMMARY

In one aspect, there is provided an object holding device including: a holding unit that holds an object and is driven in a first direction, which is a scanning direction of the object, and a second direction orthogonal to the first direction in a horizontal plane; and a pair of linear motors that apply a thrust in the first direction and a thrust in the second direction to the holding unit, each of the pair of linear motors including a first unit and a second unit, the first unit including a plurality of armature modules, each of the armature modules including a magnetic core having two or more protruding portions, which protrude in the second direction, and a coil wound around the magnetic core, currents of the same phase flowing through the coil, and the second unit including a magnet module that includes a plurality of permanent magnets arranged in the first direction while changing poles and is arranged between two adjacent protruding portions of the two or more protruding portions, wherein at least a part of each of the permanent magnets is accommodated in a space sandwiched between the two adjacent protruding portions.

In a second aspect, there is provided an exposure device including: the above object holding device; and a pattern formation device that forms a pattern that the object has onto an exposure target by an exposure operation of exposing the exposure target with an energy beam through the object held by the object holding device.

In a third aspect, there is provided an object moving method including: arranging a pair of first units so that a first direction is orthogonal to a scanning direction of an object, each of the pair of first units having a plurality of armature modules, each of the armature modules including a magnetic core having two or more protruding portions, which protrude in the first direction, and a coil wound around the magnetic core, currents of the same phase flowing through the coil; arranging a pair of second units each having a magnet module that includes a plurality of permanent magnets arranged in a second direction while changing poles in the second direction and is arranged between two adjacent protruding portions of the two or more protruding portions so that the second direction is parallel to the scanning direction and at least a part of each of the permanent magnets is accommodated in a space sandwiched between the two adjacent protruding portions; and applying a thrust in the scanning direction and a thrust in a direction orthogonal to the scanning direction in a horizontal plane to a holding unit that holds the object by a pair of linear motors each including the first unit and the second unit to move the object in the scanning direction and the direction orthogonal to the scanning direction.

In a fourth aspect, there is provided an object holding system including: a holding unit that holds an object and is driven in a first direction, which is a scanning direction of the object, and a second direction orthogonal to the first direction in a horizontal plane; a pair of linear motors that apply a thrust in the first direction and a thrust in the second direction to the holding unit, each of the pair of linear motors including a first unit and a second unit, the first unit having a plurality of armature modules, each of the armature modules including a magnetic core having two or more protruding portions, which protrude in the second direction, and a coil wound around the magnetic core, currents of the same phase flowing through the coil, the second unit having a magnet module that includes a plurality of permanent magnets arranged in the first direction while changing poles and is arranged between two adjacent protruding portions of the two or more protruding portions; and a control device configured to control the pair of linear motors, wherein at least a part of each of the permanent magnets is accommodated in a space sandwiched between the two adjacent protruding portions.

The configuration of the embodiments described below may be modified appropriately, and at least one or some of the components may be substituted for other components. Further, the constituent elements whose arrangement is not particularly limited are not limited to the arrangement disclosed in the embodiment, and can be arranged at positions where the functions can be achieved.

### BRIEF DESCRIPTION OF DRAWINGS

FIG. 1 is a schematic view illustrating a configuration of an exposure device according to an embodiment;

FIG. 2A is a plan view of a mask stage device according to the embodiment, and FIG. 2B is a side view of the mask stage device according to the embodiment;

FIG. 3A is a perspective view illustrating a configuration of a linear motor, and FIG. 3B is a side view for describing an arrangement of a first unit and a second unit in the embodiment;

FIG. 4A and FIG. 4B are side views for describing a force generated between the first unit and the second unit, and FIG. 4C is a side view for describing a thrust force in the Y-axis direction applied to a stage body;

FIG. 5 is a block diagram illustrating a configuration of a mask stage control device that controls the driving of the first linear motor and the second linear motor; and

FIG. 6A is a plan view of the mask stage device according to a variation, and FIG. 6B is a side view of the mask stage device according to the variation.

### DESCRIPTION OF EMBODIMENTS

As described above, for example, a linear motor is used as a driving device for driving the mask stage in the scanning direction. The mask stage is configured as a three degree-of-freedom (DOF) plane stage with the X-axis, Y-axis, and θz-axis having degrees of freedom on a plane in order to synchronize with the substrate stage.

When a linear motor with a core, which is a highly efficient linear motor having a large flux density, is used to meet the demand for higher driving speed of the mask stage, it is difficult to implement the linear motor to a 3-DOF plane stage such as the mask stage because a strong magnetic attraction force is generated between the core portion and the permanent magnets in a typical linear motor with a core. In the present embodiment, a linear motor with a core having a large magnetic flux density and high efficiency is implemented to the mask stage to achieve higher driving speed of the mask stage and position control of the mask stage in the X-axis direction, the Y-axis direction, and the θz direction.

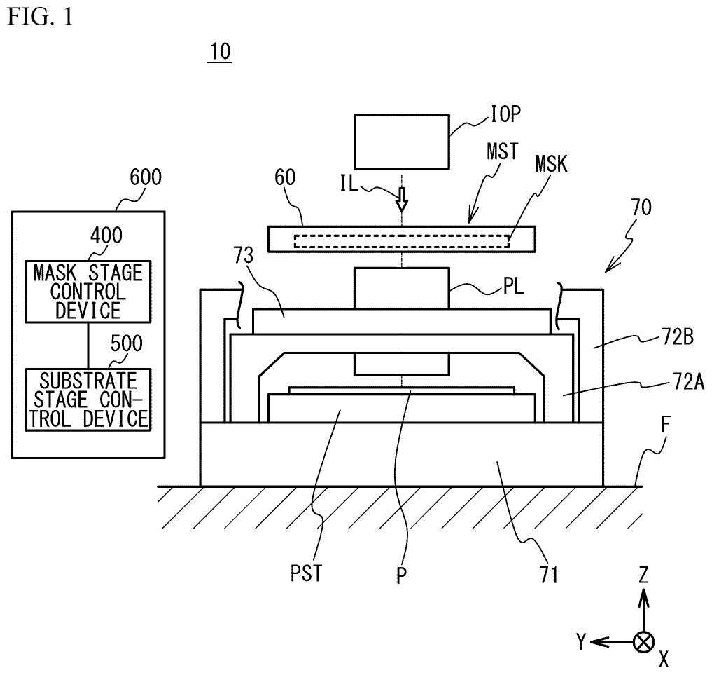

An exposure device 10 according to an embodiment will be described with reference to FIG. 1 to FIG. 5.

### (Configuration of Exposure Device)

FIG. 1 is a view schematically illustrating a configuration of the exposure device 10 according to an embodiment.

The exposure device 10 is a scanning stepper (scanner) that transfers the pattern formed on a mask MSK onto a glass substrate (hereinafter referred to as a “substrate”) P by driving the mask MSK and the substrate P in the same direction at the same speed with respect to a projection optical system PL. The substrate P is, for example, a rectangular glass substrate used for a liquid crystal display device (flat panel display), and at least one side or diagonal of the substrate P is equal to or longer than 500 mm.

In the following description, the direction (scanning direction) in which the mask MSK and the substrate P are driven during scanning exposure is defined as the X-axis direction, the direction orthogonal to the X-axis direction in the horizontal plane is defined as the Y-axis direction, the direction orthogonal to the X-axis and Y-axis is defined as the Z-axis direction, and the rotational (tilt) directions about the X-axis, Y-axis, and Z-axis are defined as the θx, θy, and θz directions, respectively. Further, the position in the X-axis direction, the position in the Y-axis direction, and the position in the θz direction of a stage body 60 of a mask stage device MST to be described later will be sometimes referred to as the X position, the Y position, and the θz position, respectively.

The exposure device 10 includes an illumination system IOP, the mask stage device MST that holds the mask MSK, the projection optical system PL, a body 70 that supports these components, a substrate stage PST that holds a substrate P, and a control device 600. The control device 600 includes a mask stage control device 400 that controls the mask stage device MST, and a substrate stage control device 500 that controls the substrate stage PST.

The body 70 includes a base (vibration isolator) 71, columns 72A and 72B, and an optical surface plate 73. The base (vibration isolator) 71 is placed on the floor F, and supports the columns 72A and 72B, and the like while isolating vibration from the floor F. The columns 72A and 72B each have a frame shape, and the column 72B is disposed inside the column 72A. The optical surface plate 73 has a flat plate shape and is fixed to the ceiling of the column 72A.

The illumination system IOP is arranged above the body 70. The illumination system IOP irradiates the mask MSK with the illumination light IL.

The mask stage device MST includes the stage body 60, on which the mask MSK having a pattern surface (the lower surface in FIG. 1) on which a circuit pattern is formed is fixed by, for example, vacuum suction (or electrostatic adsorption). The mask stage device MST is driven by a pair of linear motors 100 (described later) in the scanning direction (X-axis direction) with a predetermined stroke, and is finely driven in non-scanning directions (Y-axis direction and θz direction). The configuration of the mask stage device MST will be described later in detail.

The projection optical system PL is supported by the optical surface plate 73 below (at the −Z side of) the mask stage device MST. The projection optical system PL forms, for example, a rectangular image field whose longitudinal direction is the Y-axis direction. The projection area of the projection optical system PL may be referred to as an exposure area.

When the illumination area on the mask MSK is illuminated with the illumination light IL from the illumination system IOP, a projection image (partial erect image) of the circuit pattern of the mask MSK in the illumination area is formed on the irradiation area (exposure area (conjugate to the illumination area)) on the substrate P arranged on the image plane side of the projection optical system PL through the projection optical system PL by the illumination light IL transmitted through the mask MSK. Here, a resist (sensitive agent) is applied to the surface of the substrate P. The mask stage device MST and the substrate stage PST are synchronously driven, that is, the mask MSK is driven in the scanning direction (X-axis direction) with respect to the illumination area (illumination light IL) and the substrate P is driven in the same scanning direction with respect to the exposure area (illumination light IL), whereby the substrate P is exposed and the pattern of the mask MSK is transferred onto the substrate P.

The substrate stage PST is arranged on the base (vibration isolator) 71 below (at the −Z side of) the projection optical system PL. The substrate P is held on the substrate stage PST via a substrate holder (not illustrated).

The position information (including rotation information (the yawing amount (rotation amount θz in the θz direction), the pitching amount (rotation amount θx in the θx direction), the rolling amount (rotation amount θy in the θy direction)) of the substrate stage PST in the XY plane is measured by the interferometer system. The interferometer system measures the position of the substrate stage PST by emitting a measurement beam from the optical surface plate 73 onto a moving mirror (or a mirror-finished reflective surface (not illustrated)) on the end portion of the substrate stage PST, and receiving the reflected light from the moving mirror. The measurement results are supplied to the substrate stage control device 500, and the substrate stage control device 500 drives the substrate stage PST in accordance with the measurement results of the interferometer system.

The exposure device 10 performs alignment measurement (for example, EGA or the like) prior to exposure, and performs the exposure of the substrate P using the results of the measurement according to the following procedure. First, the mask stage device MST and the substrate stage PST are synchronously driven in the X-axis direction in accordance with instructions from the mask stage control device 400 and the substrate stage control device 500. Then, scanning exposure is performed on the first shot area on the substrate P. When the scanning exposure for the first shot area is completed, the substrate stage control device 500 moves (steps) the substrate stage PST to a position corresponding to the second shot area. Then, scanning exposure is performed on the second shot area. The substrate stage control device 500 repeats stepping between shot areas of the substrate P and scanning exposure for the shot areas in the same manner. As a result, the pattern of the mask MSK is transferred to all the shot areas on the substrate P.

### (Configuration of Mask Stage Device MST)

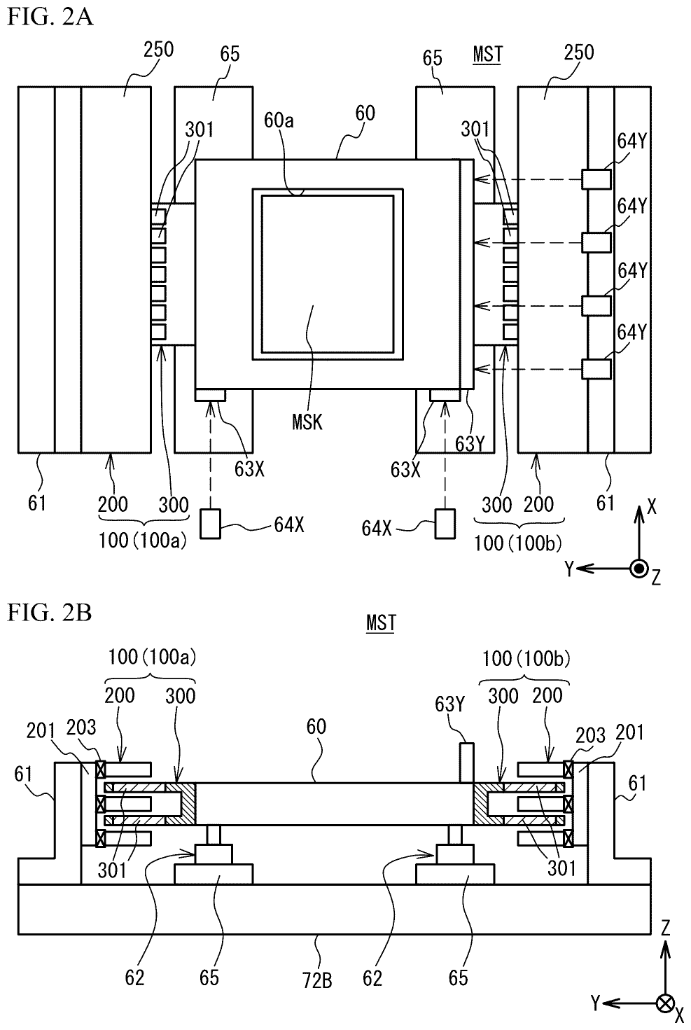

Next, the configuration of the mask stage device MST in the present embodiment will be described. FIG. 2A is a plan view of the mask stage device MST, and FIG. 2B is a side view of the mask stage device MST. In FIG. 2B, a second unit 300 described later is illustrated in a cross section including a permanent magnet 301 described later. In FIG. 2B, some components are not illustrated.

As illustrated in FIG. 2A and FIG. 2B, the mask stage device MST includes a pair of X beams 61, the stage body 60 that holds the mask MSK, a pair of linear motors 100 that apply thrust to the stage body 60, and the like.

The pair of X beams 61 are fixed to, for example, the column 72B. The pair of X beams 61 are members extending in the X-axis direction, and are arranged in parallel to each other, separated in the Y-axis direction.

The stage body 60 is formed of a plate-like member that is rectangular in a plan view, and an opening 60a in the form of a rectangular long hole whose longitudinal direction is in the X-axis direction is formed in the center portion of the stage body 60. The mask MSK is inserted into the opening 60a. A plurality of (for example, five) holding members (not illustrated) including suction pads for sucking and holding the mask MSK from below are attached to each of the wall surfaces on the +Y side and the −Y side of the wall surfaces defining the opening 60a at predetermined intervals in the X-axis direction.

Further, air bearings 62, which are a type of static gas bearing, are attached to the lower surface of the stage body 60, for example, in the vicinities of the four corners of the lower surface of the stage body 60 (see FIG. 2B). The stage body 60 floats in a non-contact manner via a minute clearance over a surface plate 65 supported by the column 72B, by blowing pressurized gas from, for example, the four air bearings 62.

Further, as illustrated in FIG. 2A, a pair of X moving mirrors 63X having a reflecting surface orthogonal to the X-axis are attached to the side surface on the −X side of the stage body 60 at a predetermined interval in the Y-axis direction. Further, a Y moving mirror 63Y (bar mirror) having a reflecting surface orthogonal to the Y-axis is attached to the side surface on the −Y side of the stage body 60.

The positional information of the stage body 60 (that is, the mask MSK) in the XY plane is constantly detected at a resolution of, for example, about 0.5 to 1 nm by a laser interferometer system (hereinafter referred to as a mask interferometer system) including a pair of X laser interferometers 64X corresponding to the pair of X moving mirrors 63X, respectively, and Y laser interferometers 64Y corresponding to the Y moving mirror 63Y. The position information of the stage body 60 in the θz direction is obtained based on the outputs of the pair of X laser interferometers 64X.

The stage body 60 is driven in the X-axis direction, the Y-axis direction, and the θz direction by a pair of linear motors 100. The pair of linear motors 100 are opposed to each other in the Y-axis direction with the stage body 60 interposed therebetween. To be more specific, the pair of linear motors 100 includes a first linear motor 100a arranged at the +Y side of the stage body 60 and a second linear motor 100b arranged at the −Y side of the stage body 60.

### (Configuration of Linear Motor 100)

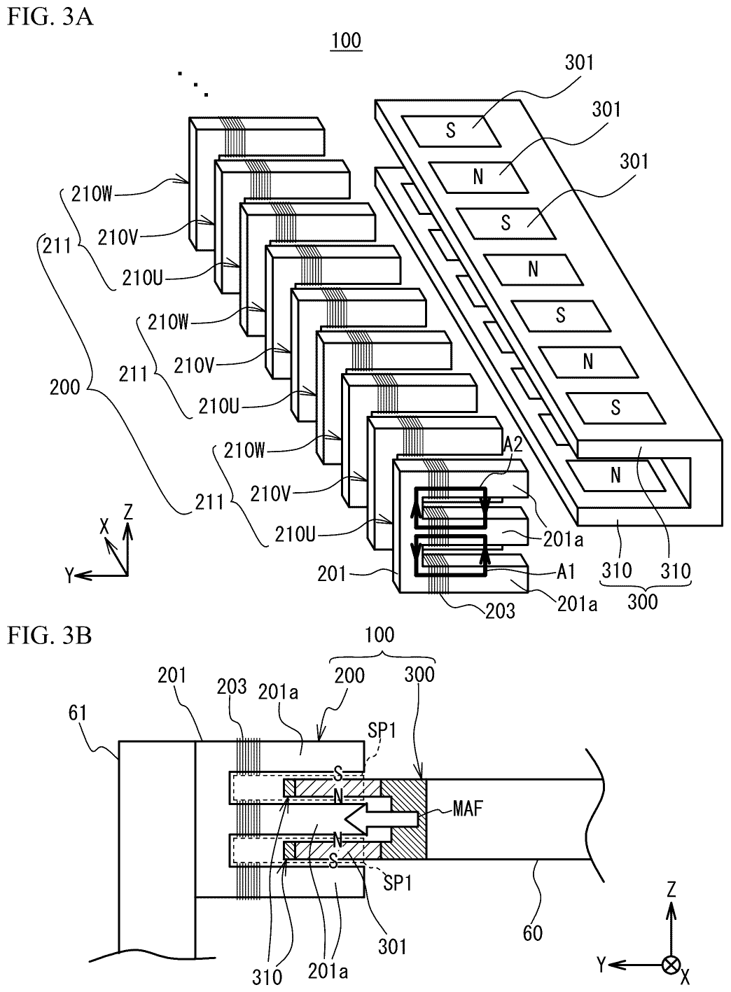

Next, a configuration of the linear motor 100 will be described. FIG. 3A is a perspective view illustrating the configuration of the linear motor 100. As illustrated in FIG. 3A, the linear motor 100 includes a first unit 200 and the second unit 300.

The first unit 200 includes a plurality of armature module sets 211 arranged in the X-axis direction. Each armature module set 211 includes armature modules 210U, 210V, and 210W. In the following description, the armature modules 210U, 210V, and 210W are referred to as armature modules 210 when no particular distinction is necessary. The armature modules 210U, 210V, and 210W are housed in a housing 250 (see FIG. 2A) having an E-shaped cross section, for example.

Each armature module 210 includes a magnetic core 201 having three protruding portions 201a that protrude in the Y-axis direction, and a coil 203 wound around the magnetic core 201. A U-phase voltage is applied to the coil 203 of the armature module 210U, a V-phase voltage is applied to the coil 203 of the armature module 210V, and a W-phase voltage is applied to the coil 203 of the armature module 210W. That is, currents in the same phase (U phase) flow through the coils 203 of the armature modules 210U, respectively. Further, currents in the same phase (V phase) flow through the coils 203 of the armature modules 210V, respectively. Further, currents in the same phase (W phase) flow through the coils 203 of the armature modules 210W, respectively.

In each of the armature modules 210U, 210V, and 210W, the winding directions of the coils 203 through which currents in the same phases flow are adjusted so that the magnetic flux closed loops are formed so that the polarities of the electromagnets of the respective protruding portions 201a are different from each other. For example, as illustrated in the armature module 210U of FIG. 3A, the winding direction of each coil 203 is adjusted so that the magnetic flux closed loops formed at a certain point of time are the magnetic flux closed loops A1 and A2.

The second unit 300 includes a magnet module 310 including a plurality of permanent magnets 301. In the present embodiment, the second unit 300 includes two magnet modules 310. In each magnet module 310, the plurality of permanent magnets 301 are arranged while changing the poles in the X-axis direction.

FIG. 3B is a side view for describing the arrangement of the first unit 200 and the second unit 300 in the present embodiment. In FIG. 3B, a cross section including the permanent magnet 301 is illustrated for the second unit 300. As illustrated in FIG. 3B, each magnet module 310 is disposed between two adjacent protruding portions 201a of the magnetic core 201 of the armature module 210. In FIG. 3A and FIG. 3B, “N” and “S” represent the N pole and the S pole of the permanent magnet 301, respectively.

The coil 203 of at least one armature module 210 is supplied with a current having a different phase from that of the current supplied to the coil 203 of another armature module 210 so that a thrust in the X-axis direction is generated by the attraction and repulsion forces between the poles of the electromagnets formed at the ends of the protruding portions 201a of each armature module 210 and the corresponding permanent magnets 301. As the linear motor 100 having the above-described configuration, for example, a linear motor disclosed in Japanese Patent No. 5956993 can be adopted.

In the present embodiment, as illustrated in FIG. 2B and FIG. 3B, the first unit 200 is fixed to the X beam 61, and the second unit 300 is fixed to the stage body 60. In the present embodiment, the first unit 200 and the second unit 300 are arranged so that a part of each of the plurality of permanent magnets 301 included in the magnet module 310 is accommodated in the space SP1 sandwiched between two adjacent protruding portions 201a of the magnetic core 201, and the other part of each of the plurality of permanent magnets 301 is exposed from the space SP1. As a result, as illustrated in FIG. 3B, a magnetic attraction force MAF is generated between the first unit 200 and the second unit 300 in the Y-axis direction. It is sufficient if at least a part of each of the plurality of permanent magnets 301 is accommodated in the space SP1 sandwiched between two adjacent protruding portions 201a of the magnetic core 201.

The magnitude of the magnetic attraction force MAF generated between the first unit 200 and the second unit 300 varies depending on the area of the portion of the permanent magnet 301 that is accommodated in the space SP1 sandwiched between the two adjacent protruding portions 201a of the magnetic core 201. In the linear motor 100 according to the present embodiment, when the entire permanent magnet 301 is accommodated in the space SP1, the magnetic attraction force MAF is the smallest. Since a large magnetic attraction force MAF between the first unit 200 and the second unit 300 affects the driving of the linear motor 100, conventionally, when the linear motor 100 according to the present embodiment is used, the first unit 200 and the second unit 300 are arranged so that the entire permanent magnet 301 is accommodated in the space SP1.

The inventor has found that the thrust in the Y-axis direction applied to the stage body 60 by the first linear motor 100a and the thrust in the Y-axis direction applied to the stage body 60 by the second linear motor 100b can be changed by the d-axis current by generating the magnetic attraction force MAF having an appropriate magnitude between the first unit 200 and the second unit 300.

Therefore, in the present embodiment, the magnetic attraction force MAF is intentionally generated between the first unit 200 and the second unit 300, and the d-axis current applied to the coil 203 is changed, whereby the thrust in the Y-axis direction applied to the stage body 60 is changed in each of the first linear motor 100a and the second linear motor 100b by the forces caused by the increase and decrease of the magnetic fluxes due to the d-axis current. This allows the thrust of the stage body 60 in the Y-axis direction to be adjusted, and allows the position of the stage body 60 in the Y-axis direction to be adjusted.

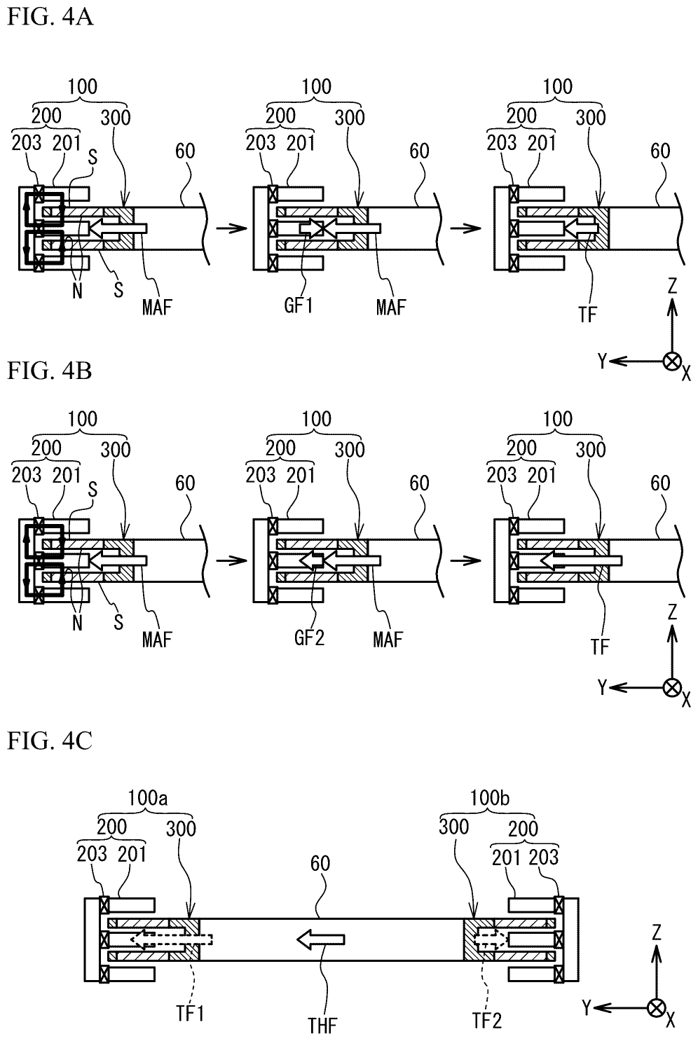

The control of the position of the stage body 60 in the Y-axis direction by the control of the d-axis current will be described in detail. FIG. 4A and FIG. 4B are side views for describing the forces generated between the first unit 200 and the second unit 300, and FIG. 4C is a side view for describing the thrust in the Y-axis direction applied to the stage body 60. FIG. 4A to FIG. 4C illustrate a cross section including the permanent magnet 301, for the second unit 300.

The left side of FIG. 4A illustrates a state before the d-axis current is supplied to the coil 203. The magnetic flux lines illustrated in FIG. 4A are due to the q-axis current. As illustrated in FIG. 4A, in a state where the d-axis current is not supplied to the coil 203 (d-axis current=0), a magnetic attraction force MAF is generated between the first unit 200 and the second unit 300. When a positive d-axis current is supplied to the coil 203 in the state illustrated in FIG. 4A, a force GF1 is generated between the first unit 200 and the second unit 300 due to an increase or decrease in the magnetic flux, as illustrated in the center of FIG. 4A. The force GF1 is the force opposite in direction to the magnetic attraction force MAF.

Although the magnetic attraction force MAF is also generated between the first unit 200 and the second unit 300, the magnetic attraction force MAF is weakened by the force GF1, and therefore, the total force TF of the force GF1 and the magnetic attraction force MAF becomes smaller than the magnetic attraction force MAF. As a result, the total force TF (<the magnetic attraction force MAF) of the force GF1 and the magnetic attraction force MAF is the force generated between the first unit 200 and the second unit 300, as illustrated in the right side of FIG. 4A.

The left side of FIG. 4B illustrates a state before the d-axis current is supplied to the coil 203, as in FIG. 4A. In the state of FIG. 4B, when a negative d-axis current is supplied to the coil 203, as illustrated in the center of FIG. 4B, a force GF2 is generated between the first unit 200 and the second unit 300 due to an increase or decrease in the magnetic flux. The force GF2 is the force in the same direction as the magnetic attraction force MAF.

The magnetic attraction force MAF is also generated between the first unit 200 and the second unit 300, and the magnetic attraction force MAF is strengthened by the force GF2, so that the total force TF of the force GF2 and the magnetic attraction force MAF becomes larger than the magnetic attraction force MAF. As a result, as illustrated in the right side of FIG. 4B, the total force TF (>the magnetic attraction force MAF) of the force GF2 and the magnetic attraction force MAF is generated between the first unit 200 and the second unit 300.

The first unit 200 and the second unit 300 of the first linear motor 100a and the first unit 200 and the second unit 300 of the second linear motor 100b are arranged so that the respective magnetic attraction forces MAF become magnetic attraction forces of appropriate magnitudes from the viewpoint of the position control of the stage body 60 in the Y-axis direction. Further, the magnetic attraction force MAF generated between the first unit 200 and the second unit 300 of the first linear motor 100a and the magnetic attraction force MAF generated between the first unit 200 and the second unit 300 of the second linear motor 100b may be the same or different.

In the present embodiment, as illustrated in FIG. 4C, the first linear motor 100a is arranged at the +Y side of the stage body 60, and the second linear motor 100b is arranged at the −Y side of the stage body 60. Assume that the mask stage control device 400 supplies a positive d-axis current to the second linear motor 100b and supplies a negative d-axis current to the first linear motor 100a. In this case, as illustrated in FIG. 4C, a total force TF1 in the +Y direction is applied to the stage body 60 by the first linear motor 100a, and a total force TF2 in the −Y direction is applied to the stage body 60 by the second linear motor 100b. That is, the direction of the thrust in the Y-axis direction applied to the stage body 60 by the first linear motor 100a is opposite to the direction of the thrust in the Y-axis direction applied to the stage body 60 by the second linear motor 100b.

As illustrated in FIG. 4C, since the total force TF1 in the +Y direction becomes larger than the total force TF2 in the −Y direction, a thrust THF in the +Y direction is applied to the stage body 60 as a whole, and the stage body 60 moves in the +Y direction. In this manner, the position of the stage body 60 in the Y-axis direction can be controlled by controlling the d-axis current supplied to the coil 203 of the first linear motor 100a and the d-axis current supplied to the coil 203 of the second linear motor 100b.

The d-axis current supplied to the coil 203 of the first linear motor 100a and the d-axis current supplied to the coil 203 of the second linear motor 100b can be determined by calculating the thrust applied to the stage body 60 in the Y-axis direction and distributing the thrust to the first linear motor 100a and the second linear motor 100b.

Specifically, the d-axis current supplied to the coil 203 of the first linear motor 100a and the d-axis current supplied to the coil 203 of the second linear motor 100b are determined so that the total force in the linear motor 100 located in the direction (+Y direction or −Y direction) in which the stage body 60 is to be moved (the total force in the direction in which the stage body 60 is to be moved) is larger than the total force in the other linear motor 100 (the total force in the direction opposite to the direction in which the stage body 60 is to be moved).

Here, when the d-axis currents in opposite directions are applied to the coil 203 of the first linear motor 100a and the coil 203 of the second linear motor 100b, respectively, the largest thrust can be generated in the Y-axis direction.

It is not necessary to apply the d-axis currents to the coils 203 of both the first linear motor 100a and the second linear motor 100b, and it is sufficient to apply the d-axils current to the coil 203 of at least one of the first linear motor 100a or the second linear motor 100b. That is, if the total force (total force in the direction in which the stage body 60 is to be moved) in the linear motor 100 positioned in the direction in which the stage body 60 is to be moved (+Y direction or −Y direction) is larger than the total force (total force in the direction opposite to the direction in which the stage body 60 is to be moved) in the other linear motor 100, the stage body 60 can be moved in the desired direction.

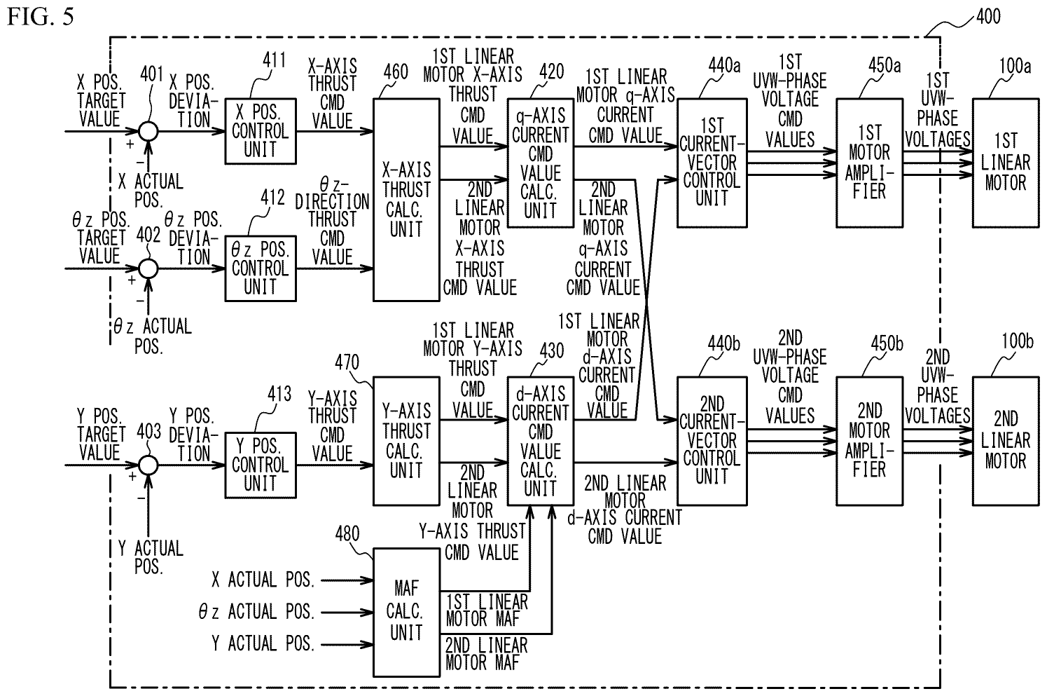

FIG. 5 is a block diagram illustrating an example of the configuration of the mask stage control device 400 that controls the driving of the first linear motor 100a and the second linear motor 100b.

The mask stage control device 400 includes adder-subtractor circuits 401 to 403, an X position control unit (X pos. control unit) 411, a θz position control unit (θz pos. control unit) 412, a Y position control unit (Y pos. control unit) 413, an X-axis thrust calculation unit (X-axis thrust calc. unit) 460, a Y-axis thrust calculation unit (Y-axis thrust calc. Unit) 470, a magnetic attraction force calculation unit (MAF calc. unit) 480, a q-axis current command value calculation unit (q-axis current cmd value calc. unit) 420, a d-axis current command value calculation unit (d-axis current cmd value calc. unit) 430, a first current-vector control unit (1st current-vector control unit) 440a, a second current-vector control unit (2nd current-vector control unit) 440b, a first motor amplifier (1 st motor amplifier) 450a, and a second motor amplifier (2nd motor amplifier) 450b.

The adder-subtractor circuit 401 calculates a deviation (X pos. deviation) between a target value of the X position of the stage body 60 input from the external device (X pos. target value) and the X position of the stage body 60 detected by the mask interferometer system (X actual pos.).

The adder-subtractor circuit 402 obtains a deviation (θz pos. deviation) between a target value of the θz position of the stage body 60 input from the external device (θz pos. target value) and the θz position of the stage body 60 detected by the mask interferometer system (θz actual pos.).

The adder-subtractor circuit 403 calculates a deviation (Y pos. deviation) between a target value of the Y position of the stage body 60 input from the external device (Y pos. target value) and the Y position of the stage body 60 detected by the mask interferometer system (Y actual pos.).

The X-position control unit 411 calculates a command value of thrust in the X-axis direction (X-axis thrust cmd value) from the deviation of the X position calculated by the adder-subtractor circuit 401.

The θz position control unit 412 calculates a command value of thrust in the θz direction (θz-direction thrust cmd value) from the deviation of the θz position calculated by the adder-subtractor circuit 402 (θz pos. deviation).

The X-axis thrust calculation unit 460 calculates a command value of the thrust in the X-axis direction of the first linear motor 100a (1st linear motor X-axis thrust cmd value) and a command value of the thrust in the X-axis direction of the second linear motor 100b (2nd linear motor X-axis thrust cmd value) based on the command value of the thrust in the X-axis direction calculated by the X position control unit 411 and the command value of the thrust in the θz direction calculated by the θz position control unit 412.

The q-axis current command value calculation unit 420 calculates a command value of the q-axis current for the first linear motor 100a (1st linear motor q-axis current cmd value) and a command value of the q-axis current for the second linear motor 100b (2nd linear motor q-axis current cmd value) based on the X-axis thrust command value of the first linear motor 100a and the X-axis thrust command value of the second linear motor 100b calculated by the X-axis thrust calculation unit 460.

On the other hand, the Y position control unit 413 calculates a command value of the thrust in the Y-axis direction (Y-axis thrust cmd value) from the deviation of the Y position (Y pos. deviation) calculated by the adder-subtractor circuit 403.

The Y-axis thrust calculation unit 470 calculates a command value of the thrust in the Y-axis direction of the first linear motor 100a (1st linear motor Y-axis thrust com value) and a command value of the thrust in the Y-axis direction of the second linear motor 100b (2nd linear motor Y-axis thrust cmd value) based on the command value of the thrust in the Y-axis direction calculated by the Y-position control unit 413.

The magnetic attraction force calculation unit 480 calculates the magnetic attraction force of the first linear motor 100a (1st linear motor MAF) and the magnetic attraction force of the second linear motor 100b (2nd linear motor MAF) from the actual position of the stage body 60. The magnetic attraction force MAF varies depending on the extent to which each permanent magnet 301 is accommodated in the space SP1 between the adjacent protruding portions 201a of the magnetic core 201. The magnetic attraction force MAF also varies when the positional relationship between the first unit 200 and the second unit 300 slightly changes due to the driving of the stage body 60 in the X-axis direction. Therefore, in the present embodiment, the magnetic attraction force calculation unit 480 calculates the positional relationship between the magnetic cores 201 and the permanent magnets 301 based on the X actual position, the Y actual position, and the θz actual position of the stage body 60, and calculates the magnetic attraction force of the first linear motor 100a and the magnetic attraction force of the second linear motor 100b from the calculated positional relationship.

The d-axis current command value calculation unit 430 calculates a d-axis current command value for the first linear motor 100a (1st linear motor d-axis current cmd value) based on the Y-axis thrust command value of the first linear motor 100a calculated by the Y-axis thrust calculation unit 470 and the magnetic attraction force of the first linear motor 100a calculated by the magnetic attraction force calculation unit 480. The d-axis current command value calculation unit 430 calculates a d-axis current command value for the second linear motor 100b (2nd linear motor d-axis current cmd value) based on the Y-axis thrust command value of the second linear motor 100b calculated by the Y-axis thrust calculation unit 470 and the magnetic attraction force of the second linear motor 100b calculated by the magnetic attraction force calculation unit 480.

The first current-vector control unit 440a calculates command values of the U-phase, V-phase, and W-phase voltages to be applied to the first linear motor 100a (1st UVW-phase voltage cmd values) based on the q-axis current command value for the first linear motor 100a calculated by the q-axis current command value calculation unit 420, the d-axis current command value for the first linear motor 100a calculated by the d-axis current command value calculation unit 430, and the actual q-axis current and the actual d-axis current of the first linear motor 100a detected by a detection unit (not illustrated), and outputs the calculated command values to the first motor amplifier 450a.

The second current-vector control unit 440b calculates command values of the U-phase, V-phase, and W-phase voltages to be applied to the second linear motor 100b (2nd UVW-phase voltage cmd values) based on the q-axis current command value for the second linear motor 100b calculated by the q-axis current command value calculation unit 420, the d-axis current command value for the second linear motor 100b calculated by the d-axis current command value calculation unit 430, and the actual q-axis current and the actual d-axis current of the second linear motor detected by the detection unit (not illustrated), and outputs the calculated command values to the second motor amplifier 450b.

The first motor amplifier 450a applies voltages of the U-phase, the V-phase, and the W-phase (1st UVW-phase voltages) to the armature modules 210U, 210V, and 210W of the first linear motor 100a, respectively, in accordance with the voltage command values of the U-phase, the V-phase, and the W-phase input from the first current-vector control unit 440a.

The second motor amplifier 450b applies voltages of the U-phase, the V-phase, and the W-phase (2nd UVW-phase voltages) to the armature modules 210U, 210V, and 210W of the second linear motor 100b, respectively, in accordance with the voltage command values of the U-phase, the V-phase, and the W-phase input from the second-current vector control unit 440b.

In this manner, the X position and the θz position of the stage body 60 can be adjusted by controlling the thrust of the first linear motor 100a in the X-axis direction and the thrust of the second linear motor 100b in the X-axis direction by the q-axis current, and the Y position of the stage body 60 can be adjusted by controlling the thrust of the first linear motor 100a in the Y-axis direction and the thrust of the second linear motor 100b in the Y-axis direction by the d-axis current.

As described in detail above, according to the present embodiment, the mask stage device MST includes the stage body 60 that holds the mask MSK and is driven in the X-axis direction, which is the scanning direction of the mask MSK, and the Y-axis direction, which is orthogonal to the X-axis direction in the horizontal plane, and the pair of linear motors 100 that apply the thrust in the X-axis direction and the thrust in the Y-axis direction to the stage body 60. Each of the pair of linear motors 100 includes the first unit 200 having a plurality of the armature modules 210U, 210V, and 210W each including: the magnetic core 201 having three protruding portions 201a; and the coil 203 wound around the magnetic core 201 and through which currents of the same phase flow, and the second unit 300 having the magnet module 310 that includes a plurality of the permanent magnets 301 arranged while changing the poles in the X-axis direction and is accommodated between two adjacent protruding portions 201a. At least a part of each of the permanent magnets 301 is accommodated in the space SP1 sandwiched between two adjacent protruding portions 201a of the magnetic core 201. Accordingly, since the magnetic attraction force MAF is generated between the first unit 200 and the second unit 300, it is possible to control the force generated between the first unit 200 and the second unit 300 by controlling the d-axis current supplied to each of the pair of the linear motors 100. As a result, the position of the stage body 60 in the Y-axis direction can be controlled by the pair of linear motors 100, and it is not necessary to provide, for example, a voice coil motor or the like for position control of the stage body 60. That is, the position of the stage body 60 in the Y-axis direction as well as the X-axis direction and the θz direction can be controlled with a simple configuration using the pair of linear motors 100. Further, the linear motor 100 according to the present embodiment includes the magnetic core 201, which allows for a higher magnetic flux density than a coreless linear motor. This allows the stage body 60 to be driven at a higher speed than a coreless linear motor. As described above, in the mask stage device MST of the present embodiment, high-speed driving of the stage body 60 and position control of the stage body 60 in three directions (the X-axis direction, the Y-axis direction, and the θz direction) can be achieved with the pair of linear motors 100.

Further, in the present embodiment, the stage body 60 is rotatable around the Z-axis direction orthogonal to the X-axis direction and the Y-axis direction. That is, the stage body 60 has three degrees of freedom. This makes it possible to synchronize the driving of the stage body 60 with the driving of the substrate stage.

Further, in the present embodiment, the pair of the linear motors 100 are opposed to each other in the Y-axis direction with the stage body 60 interposed therebetween. This allows the stage body 60 to be moved in both the +Y direction and the −Y direction.

Further, in the present embodiment, the direction of the thrust in the Y-axis direction applied to the stage body 60 by one of the pair of linear motors 100 is opposite to the direction of the thrust in the Y-axis direction applied to the stage body 60 by the other of the pair of linear motors 100. This allows the stage body 60 to be moved in both the +Y direction and the −Y direction by controlling the magnitude relationship between the two thrust forces in opposite directions.

Further, in the present embodiment, the mask stage device MST includes the mask stage control device 400 that generates and controls the generation of the d-axis current and the q-axis current supplied to the coil 203, and the mask stage control device 400 changes the thrust in the Y-axis direction applied to the stage body 60 by changing the d-axis current. This allows the position of the stage body 60 in the Y-axis direction to be changed.

Further, in the present embodiment, the mask stage control device 400 adjusts the thrust in the Y-axis direction applied to the stage body 60 by causing the d-axis current supplied to one of the pair of linear motors 100 to be different from the d-axis current supplied to the other of the pair of linear motors 100. This allows the stage body 60 to be moved in both the +Y direction and the −Y direction.

Further, in the present embodiment, the mask stage control device 400 determines the d-axis current to be supplied to each of the pair of linear motors 100 based on the difference between the target position of the stage body 60 in the Y-axis direction and the actual position of the stage body 60 in the Y-axis direction. This allows the position of the stage body 60 to be brought closer to the target position in the Y-axis direction.

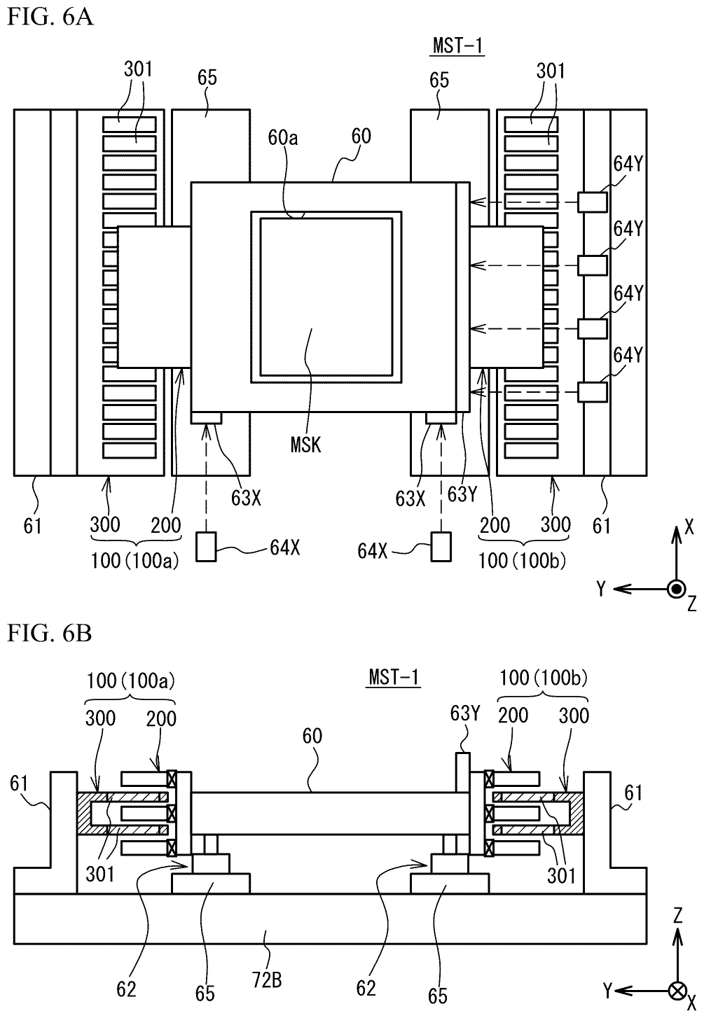

In the above embodiment above, the first unit 200 is fixed to the X beam 61, and the second unit 300 is fixed to the stage body 60, but this does not intend to suggest any limitation. FIG. 6A is a plan view of a mask stage device MST-1 according to a variation, and FIG. 6B is a side view of the mask stage device MST-1 according to the variation. FIG. 6B illustrates a cross section including the permanent magnet 301 of the second unit 300.

As illustrated in FIG. 6A and FIG. 6B, the first unit 200 may be fixed to the stage body 60, and the second unit 300 may be fixed to the X beam 61. In this case, the first unit 200 may include one armature module set 211 including the armature modules 210U, 210V, and 210W, or may include a plurality of armature module sets. Other configurations are the same as those of the embodiment, and thus detailed description thereof will be omitted.

In the above embodiment, the magnetic core 201 of the armature module 210 of the first unit 200 has three protruding portions 201a, and the second unit 300 has two magnet modules 310. However, this does not intend to suggest any limitation. For example, the magnetic core 201 of the armature module 210 of the first unit 200 may have two protruding portions 201a, and the second unit 300 may have one magnet module 310. In this case, one magnet module 310 is disposed between two protruding portions 201a. The magnetic core 201 of the armature module 210 of the first unit 200 may include N (N is a positive integer of 4 or greater) protruding portions 201a, and the second unit 300 may include N−1 magnet modules 310.

Further, in the above embodiment, the case has been described where the exposure device 10 is an exposure device that transfers the pattern of the mask MSK onto the glass substrate, but the exposure device 10 may be, for example, a semiconductor exposure device that forms a pattern formed on a reticle onto a wafer.

In addition to the exposure device 10, the above embodiment may be applied to a device that holds an object and controls its position in two directions that intersect in the horizontal plane.

The above embodiments are preferred examples. However, the present disclosure is not limited to this, and various modifications can be made without departing from the scope of the present disclosure, and arbitrary constituent features may be combined.

What is claimed is:

1. An object holding device comprising:
a holding unit that holds an object and is driven in a first direction, which is a scanning direction of the object, and a second direction orthogonal to the first direction in a horizontal plane; and
a pair of linear motors that apply a thrust in the first direction and a thrust in the second direction to the holding unit, each of the pair of linear motors including a first unit and a second unit, the first unit including a plurality of armature modules, each of the armature modules including a magnetic core having two or more protruding portions, which protrude in the second direction, and a coil wound around the magnetic core, currents of the same phase flowing through the coil, and the second unit including a magnet module that includes a plurality of permanent magnets arranged in the first direction while changing poles and is arranged between two adjacent protruding portions of the two or more protruding portions,
wherein at least a part of each of the permanent magnets is accommodated in a space sandwiched between the two adjacent protruding portions.

2. The object holding device according to claim 1, wherein another part of each of the permanent magnets, which is opposite to the protruding portions, is exposed from the space.

3. The object holding device according to claim 1, wherein the holding unit is rotatable around a third direction orthogonal to the first direction and the second direction.

4. The object holding device according to claim 1, wherein the pair of linear motors face each other in the second direction across the holding unit.

5. The object holding device according to claim 4, wherein a direction of a first thrust in the second direction applied to the holding unit by one of the pair of linear motors is opposite to a direction of a second thrust in the second direction applied to the holding unit by the other of the pair of linear motors.

6. The object holding device according to claim 1, further comprising:
a current control unit configured to generate and control a d-axis current and a q-axis current to be supplied to the coil,
wherein the current control unit changes the thrust in the second direction applied to the holding unit by changing the d-axis current.

7. The object holding device according to claim 6, wherein the current control unit adjusts the thrust in the second direction applied to the holding unit by causing a d-axis current supplied to one of the pair of linear motors to be different from a d-axis current supplied to the other of the pair of linear motors.

8. The object holding device according to claim 6, wherein the current control unit determines a d-axis current to be supplied to each of the pair of linear motors based on a difference between a target position of the holding unit in the second direction and an actual position of the holding unit in the second direction.

9. The object holding device according to claim 1, wherein the second unit is fixed to the holding unit.

10. The object holding device according to claim 1, wherein the first unit is fixed to the holding unit.

11. An exposure device comprising:
the object holding device according to claim 1; and
a pattern formation device that forms a pattern that the object has onto an exposure target by an exposure operation of exposing the exposure target with an energy beam through the object held by the object holding device.

12. An object moving method comprising:
arranging a pair of first units so that a first direction is orthogonal to a scanning direction of an object, each of the pair of first units having a plurality of armature modules, each of the armature modules including a magnetic core having two or more protruding portions, which protrude in the first direction, and a coil wound around the magnetic core, currents of the same phase flowing through the coil;
arranging a pair of second units each having a magnet module that includes a plurality of permanent magnets arranged in a second direction while changing poles in the second direction and is arranged between two adjacent protruding portions of the two or more protruding portions so that the second direction is parallel to the scanning direction and at least a part of each of the permanent magnets is accommodated in a space sandwiched between the two adjacent protruding portions; and
applying a thrust in the scanning direction and a thrust in a direction orthogonal to the scanning direction in a horizontal plane to a holding unit that holds the object by a pair of linear motors each including the first unit and the second unit to move the object in the scanning direction and the direction orthogonal to the scanning direction.

13. An object holding system comprising:
a holding unit that holds an object and is driven in a first direction, which is a scanning direction of the object, and a second direction orthogonal to the first direction in a horizontal plane;
a pair of linear motors that apply a thrust in the first direction and a thrust in the second direction to the holding unit, each of the pair of linear motors including a first unit and a second unit, the first unit having a plurality of armature modules, each of the armature modules including a magnetic core having two or more protruding portions, which protrude in the second direction, and a coil wound around the magnetic core, currents of the same phase flowing through the coil, the second unit having a magnet module that includes a plurality of permanent magnets arranged in the first direction while changing poles and is arranged between two adjacent protruding portions of the two or more protruding portions; and
a control device configured to control the pair of linear motors,
wherein at least a part of each of the permanent magnets is accommodated in a space sandwiched between the two adjacent protruding portions.
